(19) United States
(12) Patent Application Publication
(10) Pub. No.: US 2020/0216947 A1
(43) Pub. Date: Jul. 9, 2020

(54) METHOD FOR PRODUCING COMPONENTS AND COMPONENTS PRODUCED IN ACCORDANCE WITH SAID METHOD

(71) Applicant: Schaeffler Technologies AG & Co. KG, Herzogenaurach (DE)

(72) Inventors: Moritz Wegener, Erlangen (DE); Yashar Musayev, Nürnberg (DE); Ladislaus Dobrenizki, Höchstadt (DE)

(73) Assignee: Schaeffler Technologies AG & Co. KG, Herzogenaurach (DE)

(21) Appl. No.: 16/637,888

(22) PCT Filed: Jul. 27, 2018
(86) PCT No.: PCT/DE2018/100669

§ 371 Date: Feb. 10, 2020

(30) Foreign Application Priority Data
Aug. 11, 2017 (DE) 10 2017 118 320.5

(51) Int. Cl. C23C 14/56; C23C 14/16; C23C 14/06; H01M 8/021; H01M 8/0228

(52) U.S. Cl. CPC C23C 14/562; C23C 14/16; C23C 14/0635; H01M 2008/1095; H01M 8/021; H01M 8/0228; C23C 14/0641

(57) ABSTRACT

A method for producing components, in particular for energy systems such as fuel cells or electrolyzers, has the following steps: rolling-off a metal sheet having a thickness of less than 500 μm, from a first roll; transporting the metal sheet through at least one coating plant in which the metal sheet is coated on at least one side by means of a physical and/or chemical vapor deposition process; performance of at least one forming process on the coated metal sheet; formation of a plurality of components by parting from the coated metal sheet; and rolling-up of the remaining coated metal sheet to give a second roll, with continuous transport of the metal sheet from the first roll to the second roll being carried out.

### CROSS-REFERENCE TO RELATED APPLICATIONS

This application is the U.S. National Phase of PCT Appln. No. PCT/DE2018/100669 filed Jul. 27, 2018, which claims priority to DE 10 2017 118 320.5 filed Aug. 11, 2018, the entire disclosures of which are incorporated by reference herein.

### TECHNICAL FIELD

The disclosure relates to a process for producing components, in particular components for energy systems such as fuel cells or electrolyzers. The disclosure further relates to components produced by the process. The disclosure further relates to a bipolar plate and also a fuel cell or an electrolyzer comprising such a bipolar plate.

### BACKGROUND

Electrochemical systems such as fuel cells, in particular polymer electrolyte fuel cells, and conductive, current-collecting plates for such fuel cells and electrolyzers and also current collectors in electrochemical cells and electrolyzers are known.

An example is the bipolar or monopolar plates in fuel cells, in particular in an oxygen half cell. The bipolar or monopolar plates are configured in the form of carbon plates (e.g. Grafoil plates) which contain carbon as the main constituent. These plates tend to be brittle and are comparatively thick, so that they significantly reduce a performance volume of the fuel cell. A further disadvantage is their unsatisfactory physical (e.g. thermomechanical) and/or chemical and/or electrical stability.

The production of the current-collecting plates of the fuel cell from metallic (in particular austenitic) stainless steels is likewise known. On this subject see, for example, DE 10 2010 026 330 A1. The advantage of these plates is an achievable lower thickness of the plates. This is desirable because both a construction space and a weight of the fuel cell can be kept as small as possible. However, production of such plates is complicated since they have to be provided with conductor tracks and usually also with a surface coating which protects against corrosion. The production process for such bipolar plates is therefore at present not yet satisfactorily efficient in respect of the production costs.

DE 10 2009 056 728 A1 discloses the production of a sheet metal component by forming of a cut-to-size metal sheet. A disadvantage is said to be that a coating applied before the forming step can be damaged by subsequent forming.

DE 10 2010 056 016 A1 discloses an apparatus for producing a bipolar plate, wherein a roll-to-roll process is used in the processing of metal substrate strips. Here, two metal substrate strips are processed in parallel in order to form an anode plate and a cathode plate which are then joined by laser welding to give a bipolar plate. For the in-line process described, a description is given of the execution of forming processes, parting processes, alignment processes, coating processes, cleaning processes, folding processes, heating processes, cooling processes and/or further processes which are carried out at the same time for each metal substrate strip.

DE 100 58 337 A1 discloses a sheet metal product for use as bipolar plate, which has a coating composed of a metal oxide on at least one side. The plate has a shape produced by forming, with the coating being able to be applied to the metal sheet before or after the forming process.

### SUMMARY

It is therefore desirable to provide a more efficient process for producing components, in particular components for energy systems such as fuel cells or electrolyzers.

A process for producing components, in particular components for energy systems such as fuel cells or electrolyzers, includes the following steps:

a) provision of a first roll of metal sheet having a thickness of the material of the metal sheet of less than 500 μm;
b) rolling-off of the metal sheet from the first roll by transporting a first end of the first roll in a direction of advance;
c) transport of the first end of the first roll and subsequent regions of the metal sheet through at least one coating plant in which the metal sheet is coated on at least one side by means of a physical and/or chemical vapor deposition process;
d) performance of at least one forming process on the coated metal sheet;
e) formation of a plurality of components by parting from the coated metal sheet;
f) rolling-up of the remaining coated metal sheet to give a second roll, with continuous transport of the metal sheet from the first roll to the second roll being carried out.

The metal sheet is coated in a roll-to-roll process. After this, forming of the coated metal sheet and individualization to give components made of the coated metal sheet is carried out. The process simplifies the handling of the metal sheet during coating and makes rapid and automated handling of the coated metal sheet possible. The webs of the coated metal strip remaining after cutting-out of the components are rolled up to give a second roll. The coating on the metal sheet is surprisingly only insignificantly damaged, if at all, by the subsequent forming and parting processes, so that the electrical properties are suitable for use of the components in energy systems.

When the first roll of metal sheet approaches its end, with the second end of the metal sheet opposite the first end becoming detached from a reel, this second end of the metal sheet may be joined to the first end of a fresh first roll of metal sheet, for example by welding. The production process can thus be operated in an automated manner and continuously “in-line” from roll to roll.

In an embodiment of the process, a metal sheet which has a thickness of the material in the range from 100 to 200 μm is used. The metal sheet may be made of steel or stainless steel, in particular austenitic stainless steel. As an alternative, it is possible to use a metal sheet composed of titanium or a titanium alloy.

The at least one forming process may include deep drawing and/or extrusion and/or hydroforming. However, other forming processes as defined in DIN 8582 and also cutting-through of the metal sheet can also be carried out on the previously coated metal sheet.

The formation of gas distributor structures which are usually provided for bipolar plates may be carried out by forming and/or shear cutting.

The parting of a component from the coated and formed metal sheet is carried out, in particular, by means of shear cutting, preferably by stamping.

In particular, a layer system comprising a covering layer facing away from the metal sheet is applied to the metal sheet by means of at least one coating plant, with the covering layer being formed by a homogeneous or heterogeneous solid metallic solution which either contains a first chemical element from the group of the noble metals in the form of iridium in a concentration of at least 99% or

contains a first chemical element from the group of the noble metals in the form of iridium and a second chemical element from the group of the noble metals in the form of ruthenium, with the first chemical element and the second chemical element being present in a total concentration of at least 99%,

and additionally contains at least one nonmetallic chemical element from the group consisting of nitrogen, carbon, and fluorine, with oxygen and/or hydrogen optionally also being present only in traces.

This covering layer has excellent suitability for the process and has sufficient ductility for it to be only insignificantly damaged, if at all, by forming processes carried out after application to the metal sheet. Such a covering layer continues to be sufficiently electrically conductive and electrocatalytically active and also protects against corrosion even after the forming and parting processes.

A homogeneous metallic solution (type 1) is a material in which the nonmetallic chemical elements mentioned are dissolved in the metal lattice in such a way that the lattice type of the host metal or the host metal alloy remains essentially unchanged.

A heterogeneous metallic solution is a material in which one of the nonmetallic chemical elements is present in elemental form in a mixed phase in addition to the metal-containing phase. For example, depending on the configuration of the phase diagram, elemental carbon can be present in addition to the alpha phase (type 1).

Depending on deposition conditions, the layer can be metastable or stable in the thermodynamic sense.

It has been found that use of a carbon-containing covering layer, thus the use of the metalloid or nonmetallic chemical element carbon, results in the conductivity of the covering layer being higher than in the case of gold and its oxidation stability in an acidic solution is at the same time significantly above a voltage of 2000 mV relative to a standard hydrogen electrode. Measured specific electrical resistances are, depending on embodiment, comparable with gold (under standardized conditions, i.e. at a contact pressure of 140 N/cm²). The specific electrical resistance of gold is about 10 mΩcm⁻² at room temperature (T=20° C.).

A further important advantage is that iridium does not oxidize and go into solution at voltages above the value E=2.04−0.059 lg pH-−0.0295 lg (IrO₄)²⁻. In solid solution, the low-valent iridium is thus stabilized to such an extent that an otherwise usual oxidation at about 1800 mV in 1 mol/l (1N-concentrated) sulfuric acid (H₂SO₄) no longer takes place. The stabilization is due to the gain of free partial mixing energy ΔGₘᵢₓ of the solid solutions or compounds.

The covering layer is preferably applied in a layer thickness of from at least 1 nm to a maximum of 10 nm. Despite this very low layer thickness, forming of the coated metal sheet is surprisingly possible.

The at least one nonmetallic chemical element, i.e. carbon and/or nitrogen and/or fluorine, is preferably present in a concentration in the range from 0.1% to 1% in the covering layer. In particular, the nonmetallic chemical element carbon is present in the concentration range from 0.10 to 1% in the covering layer. In particular, the nonmetallic chemical element nitrogen is present in the concentration range from 0.10 to 1% in the covering layer. In particular, the nonmetallic chemical element fluorine is present in the concentration range up to a maximum 0.5% in the covering layer.

A covering layer which

a) comprises at least 99% of iridium and additionally carbon; or
b) comprises at least 99% of iridium and additionally carbon and traces of oxygen and/or hydrogen; or
c) comprises at least 99% of iridium and additionally carbon and fluorine, optionally additionally traces of oxygen and/or hydrogen; or
d) comprises a total of from at least 15 to 98.9% of iridium and from 0.1 to 84% of ruthenium and additionally carbon; or
e) comprises a total of from at least 15 to 98.9% of iridium and from 0.1 to 84% of ruthenium and additionally carbon and traces of oxygen and/or hydrogen; or
f) comprises a total of from at least 15 to 98.9% of iridium and from 0.1 to 84% of ruthenium and additionally carbon and fluorine, optionally also traces of oxygen and/or hydrogen, has been found to be particularly useful.

Furthermore, the covering layer can contain at least one chemical element from the group of the base metals. The at least one chemical element from the group of the base metals is preferably formed by aluminum, iron, nickel, cobalt, zinc, cerium or tin and/or is present in the concentration range from 0.005 to 0.01% in the coating.

In a further advantageous embodiment of the covering layer, it comprises at least one chemical element from the group of the refractory metals, in particular titanium and/or zirconium and/or hafnium and/or niobium and/or tantalum. It has been found that the addition of the refractory metals additionally enables H₂O₂ and ozone formed in proportions during the electrolysis to be controlled.

A further advantage of the utilization of these metals, either in elemental form or in the form of compounds, is that they form self-protecting, stable and conductive oxides under corrosion conditions.

The covering layer comprising at least one refractory metal having a high conductivity and a high corrosion resistance, in particular in a temperature range from 0 to about 200° C. Excellent properties for long-term use in, for example, fuel cells are thus established.

A further advantage is given by coating of electric conductors such as, in particular, metallic bipolar plates, regardless of whether the electric conductor is, for example, a bipolar plate, configured for low-temperature polymer electrolyte fuel cells or for high-temperature polymer electrolyte fuel cells.

The at least one chemical element from the group of the refractory metals is preferably present in the concentration range from 0.005 to 0.01% in the covering layer.

If the at least one chemical element from the group of the base metals is present in the form of tin, this and the at least one chemical element from the group of the refractory metals are together present in the concentration range from 0.01 to 0.2% in the covering layer.

It has been found to be useful for the covering layer also to comprise at least one additional chemical element from the group of the noble metals in a concentration range from 0.005 to 0.9%. The chemical element from the group of the noble metals is, in particular, platinum, gold, silver, rhodium, palladium.

It has been found to be useful for all chemical elements from the group of the noble metals, i.e. together with iridium and ruthenium, to be present in the concentration range above 99% in the covering layer.

The corrosion protection on the metal sheet is further improved by the covering layer being applied to an undercoat system present between the metal sheet and the covering layer. This is particularly advantageous when corrosive surrounding media are present, in particular when the corrosive media are chloride-containing.

Underoxidation, i.e. oxidation of the surface of a metal sheet having a covering layer applied to this surface, normally leads to delamination of superposed noble metal layers.

The layer system therefore preferably further comprises an undercoat layer system, where the undercoat layer system comprises at least one undercoat layer comprising at least one chemical element from the group consisting of titanium, niobium, hafnium, zirconium, tantalum.

The layer system thus comprises a covering layer and an undercoat layer system, with the covering layer being arranged so as to face away from the metal sheet.

The undercoat layer system particularly comprises a first undercoat layer in the form of a metallic alloy layer comprising the chemical elements titanium and niobium, in particular 20-50% by weight of niobium with titanium as balance.

The undercoat layer system particularly further comprises a second undercoat layer comprising at least one chemical element from the group consisting of titanium, niobium, zirconium, hafnium, tantalum and additionally at least one nonmetallic element from the group consisting of nitrogen, carbon, boron, fluorine.

The second undercoat layer may comprise the chemical elements

a) titanium, niobium and additionally carbon and fluorine, or
b) titanium, niobium and additionally nitrogen.

In particular, the second undercoat layer is formed by (Ti_{0.67}Nb_{0.33})₁₋ₓNₓ where x=0.40-0.55. Here, the material referred to as (Ti_{0.67}Nb_{0.33})₁₋ₓNₓ where x=0.40-0.55 is formed by the second undercoat layer being produced by atomization of a target composed of Ti_{0.67}Nb_{0.33}, with nitrogen being incorporated in a concentration of from 40 to 55% from the gas phase into the second undercoat layer.

The second undercoat layer is preferably arranged between the first undercoat layer and the covering layer.

The second undercoat layer can additionally contain up to 5% of oxygen.

A bipolar plate comprises at least one component which has been produced by the process. In particular, such a bipolar plate comprises at least two components which are joined to one another. The components can be joined to one another by bonding, in particular welding, soldering, clinching or adhesive bonding, or else by riveting or screwing.

A fuel cell, in particular polymer electrolyte fuel cell, comprises at least one such bipolar plate. An electrolyzer likewise comprises at least one such bipolar plate.

A fuel cell of this type, in particular a polymer electrolyte fuel cell, has been found to be particularly advantageous in respect of the electrical values and the corrosion resistance combined with low production costs. In particular, it is possible to achieve oxidation stabilities at 2000 mV of less than 20 mΩcm⁻², measured as change in the surface resistance in mΩcm⁻². Such a fuel cell therefore has a long life of more than 10 years or more than 5000 motor vehicle operating hours or more than 60,000 operating hours in stationary applications.

In the case of an electrolyzer, which operates with the reverse working principle compared to a fuel cell and brings about a chemical reaction, i.e. a transformation of material, by means of electric current, comparably long lives can be achieved. In particular, the electrolyzer is one suitable for hydrogen electrolysis.

Advantageously, a thickness of the covering layer of less than 10 nm is sufficient to protect against a resistance-increasing oxidation of the second undercoat layer. To form secure corrosion protection, sublayers of the undercoat layer system are made of at least one refractory metal and are applied in at least two layers to the steel, in particular stainless steel, firstly as metal or alloy layer (=first undercoat layer) and then as metalloid layer (=second undercoat layer). The double layer formed by the two sublayers under the covering layer firstly ensures electrochemical matching to the metal sheet and secondly pore formation due to oxidation and hydrolysis processes is ruled out.

The electrochemical matching to the metal sheet is necessary because both the metalloid layer (=second undercoat layer) and the covering layer are very noble. In the event of pore formation, high local element potentials would build up, resulting in impermissible corrosion currents. The metallic first undercoat layer is preferably formed by titanium or niobium or zirconium or tantalum or hafnium or alloys of these metals which are less noble than the support material, for example in the form of steel, in particular stainless steel, and in the event of corrosion processes firstly react to form insoluble oxides or voluminous sometimes gel-like hydroxo compounds of these refractory metals. As a result, the pores grow shut and protect the underlying material or metal sheet against corrosion. The process represents self-healing of the layer system.

In particular, a second undercoat layer in the form of a nitridic layer serves as hydrogen barrier and thus protects the metal sheet, in particular composed of stainless steel, the bipolar plate and also the metallic first undercoat layer against hydrogen embrittlement.

### BRIEF DESCRIPTION OF THE DRAWINGS

Further advantages, features and details may be derived from the following description of preferred working examples and the figures.

The features and feature combinations mentioned above in the description can be used not only in the combination indicated in each case but also in other combinations or alone.

The figures thus show:

FIG. 1 a schematic process flow diagram for the proposed process;

FIG. 2 a component formed by the proposed process; and

FIG. 3 a section through the component of FIG. 2 in the region of the applied layer system.

### DETAILED DESCRIPTION

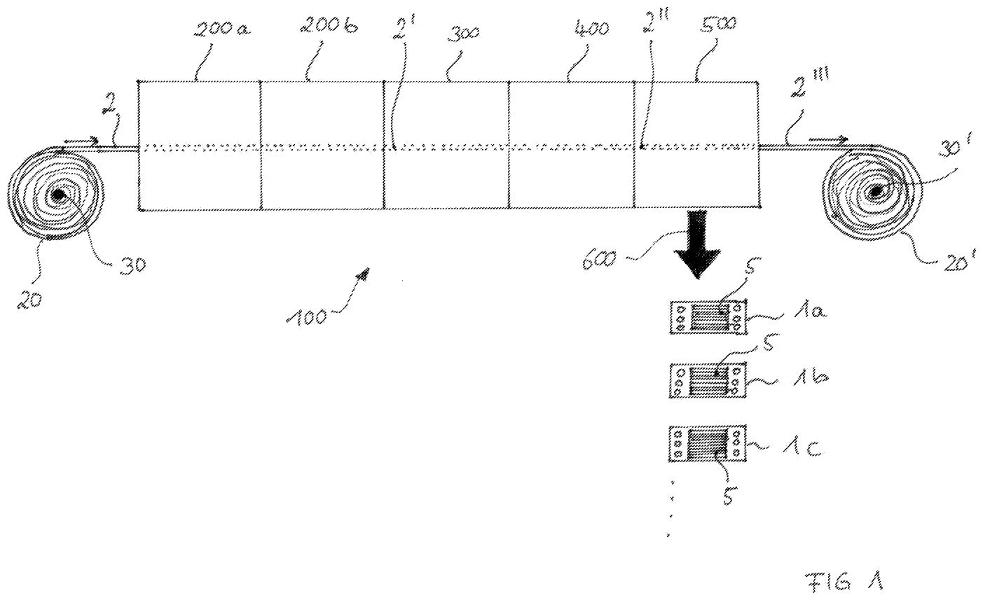

FIG. 1 schematically shows a process flow diagram for the proposed process for producing components 1a, 1b, 1c, in which a first roll 20 of metal sheet 2 is provided and the metal sheet 2 is rolled off from a first reel 30 and transported in the direction of a second reel 30′ in a roll-to-roll process.

A thickness of the material of the metal sheet 2 is less than 500 μm.

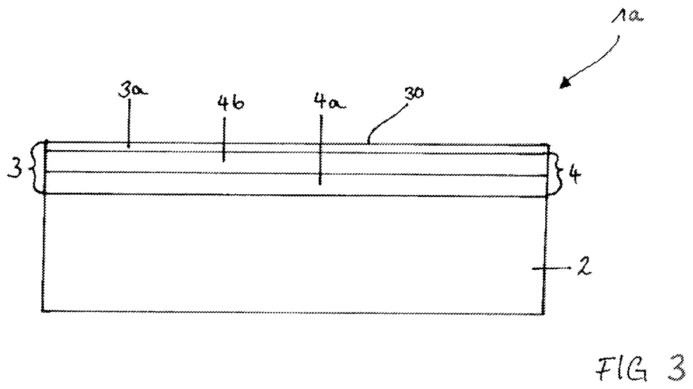

The first end of the first roll 20 and subsequent metal sheet regions are transported through at least one first coating plant 200a in which the undercoat layer system 4 (cf FIG. 3) is produced. The metal sheet 2 is coated on at least one side by means of a physical and/or chemical vapor deposition process, with full-area or only partial coating of the metal sheet 2 carried out.

The metal strip 2 and subsequent metal sheet regions are transported through at least one second coating plant 200b in which the covering layer 3a (cf FIG. 3) is produced. The metal sheet 2 is coated on at least one side by means of a physical and/or chemical vapor deposition process, at least in the region of the undercoat layer system 4.

The coated metal sheet 2′ is then transported into at least one forming unit 300. There, forming processes are carried out on the coated metal sheet 2′, in particular to produce gas distributor structures 5. Here, the coated metal sheet 2′ is deformed three-dimensionally, and optionally provided with slots or cut-outs in a further forming and/or shear cutting unit 400. The coated and formed metal sheet 2″ is fed to a stamping unit 500 in order to produce a plurality of components 1a, 1b, 1c. Parting of the components 1a, 1b, 1c from the coated, formed metal sheet 2″ is carried out. The components 1a, 1b, 1c are transported away by means of a transport unit 600.

The remaining coated metal sheet 2′″ is rolled up by means of the second reel 30′ to give a second roll 20′, with the metal sheet 2 being transported continuously from the first roll 20 to the second roll 20′. Processing of the metal strip 2 is carried out in an efficient and cost-saving manner in an in-line process.

It can be necessary to cool the coated metal sheet after passage through the at least one coating plant. For this reason, at least one cooling chamber can be installed between the at least one coating plant and the at least one forming unit. Furthermore, the at least one coating plant can be preceded by at least one vacuum chamber which serves not only for optional preheating or heating of the metal strip but especially for setting the required atmospheric pressure over the metal strip before it goes into the at least one coating plant. Thus, a physical and/or chemical vapor deposition process is usually carried out under reduced pressure.

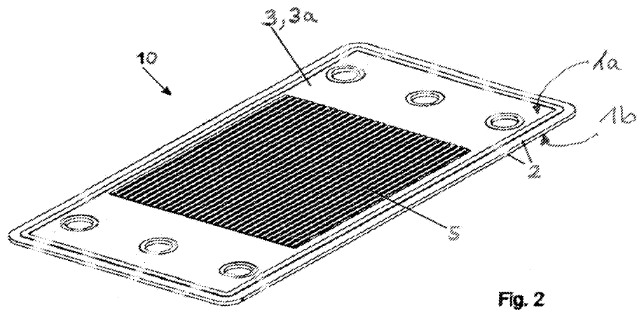

FIG. 2 shows components 1a, 1b having gas distributor structures 5 produced by the process depicted in FIG. 1, with the components 1a, 1b having been joined together by laser welding to give a bipolar plate 10. Each component 1a, 1b has a layer system 3 comprising a covering layer 3a. Reference numerals which are the same as in FIG. 1 denote identical elements.

FIG. 3 shows a section through the component 1a of FIG. 2 in the region of the applied layer system 3. The layer system 3 has been applied over the full area of one side of the metal sheet 2 composed of stainless steel. The layer system 3 comprises the covering layer 3a and the undercoat layer system 4 comprising a first undercoat layer 4a and a second undercoat layer 4b.

The metal sheet 2 has been made in the form of a conductor, here for a bipolar plate 10 of a polymer electrolyte fuel cell for the reaction of (reformed) hydrogen, from a stainless steel, in particular from an austenitic steel which satisfies very high known demands in respect of corrosion resistance, e.g. having the DIN ISO material number 1.4404.

The layer system 3 is produced on the metal sheet 2 by means of a coating process, for example a vacuum-based coating process (PVD), with the metal sheet 2 being coated in one process pass firstly with a first undercoat layer 4a, for example in the form of a 0.5 μm thick titanium layer, subsequently with a second undercoat layer 4b, for example in the form of a 1 μm thick titanium nitride layer, and subsequently with the covering layer 3a, for example in the form of a 10 nm thick iridium-carbon layer. The covering layer 3a corresponds to a layer which is open on one side since only one covering layer surface is in contact with a further layer, here the second undercoat layer 4b. Thus, a free surface of the covering layer 3a in a fuel cell is arranged directly adjoining an electrolyte, in particular a polymer electrolyte, and is exposed thereto.

In a second working example, the metal sheet 2 for the bipolar plate 10 is firstly coated with a first undercoat layer 4a in the form of a metallic alloy layer having a thickness of 100 nm, with the metallic alloy layer having the composition Ti_{0.67} Nb_{0.33}. A second undercoat layer 4b having a thickness of 400 nm and the composition (Ti_{0.67}Nb_{0.33})₁₋ₓNₓ where x=0.40-0.55 is subsequently applied. A covering layer 3a having a thickness of 10 nm and the composition iridium-carbon is then applied on top.

The advantage is an extraordinarily high stability against oxidation of the bipolar plate 10. Even at long-term application of +3000 mV relative to a standard hydrogen electrode, no increase in resistance is found in sulfuric acid solution having a pH of 3. In terms of external appearance, the free surface of the covering layer 3a, thus the surface of the covering layer 3a facing away from the metal sheet 2, remains shiny and silvery even after application of +2000 mV relative to a standard hydrogen electrode for 50 hours. Even under a scanning electron microscope, no traces of corrosion extending through the thickness of the covering layer 3a to the metal sheet 2 or reaching the metal sheet 2 can be seen.

The covering layer 3a of the second working example can be applied either by means of the vacuum-based PVD sputtering technique or by means of a cathodic ARC coating process, also known as vacuum arc deposition. Despite a higher number of droplets, in other words a number of metal droplets higher than in the sputtering technique, the covering layer 3a produced in the cathodic ARC process also has the advantageous properties of high corrosion resistance combined with time-stable surface conductivity of the covering layer 3a produced by means of the sputtering technique.

In a third working example, the layer system 3 is produced on a metal sheet 2 in the form of a structured perforated stainless steel sheet. The metal sheet 2 has been electrolytically polished in an H₂SO₄/H₃PO₄ bath before application of a layer system 3. After application of a single undercoat layer in the form of a tantalum carbide layer having a thickness of several 1000 nm, a covering layer 3a in the form of an iridium-carbon layer having a thickness of several 100 nm is applied.

The advantage of the undercoat layer composed of the tantalum carbide is not only its extraordinary corrosion resistance but also the fact that it does not absorb any hydrogen and thus serves as hydrogen barrier for the metal sheet 2. This is particularly advantageous when titanium is used as metal sheet.

The layer system 3 of the third working example is suitable for use in an electrolysis cell for producing hydrogen at current densities which are greater than 500 mA cm⁻².

The advantage of the metalloid layer or the second undercoat layer, which in the simplest case is composed of, for example, titanium nitride, which is located in an intermediate position in the layer system and/or is closed on both sides is its low electrical resistance of 10-12 mΩcm⁻². The covering layer can likewise also be produced without a second undercoat layer or metalloid layer, with a possible increase in resistance.

Some layer systems with their characteristic values are shown by way of example in Table 1.

TABLE 1
Layers and selected characteristic values

| | | | Corrosion current | |
|---|---|---|---|---|
| | | | 2000 mV relative to | |
| | | Specific | standard hydrogen | Oxidation stability at |
| | | surface | electrode in μA cm⁻² | 2000 mV measured as |
| | | resistance in | in aqueous sulfuric | change in the surface |
| | Layer system/layer | mΩ cm⁻² | acid solution | resistance in mΩ cm⁻² |
| | thickness | at T = 20° C. | (pH = 3) at T = 80° C. | Target value: <20 mΩ cm⁻² |
| 1 | Gold/3 μm | 9 | >100 pitting current | 9-10 |
| | (as reference) | | | |
| 2 | Ti/0.5 μm | 8 | 0.001 | 12 |
| | TiN/1 μm | | | |
| | Ir_{0.99}—C_{0.01}/10 nm | | | |
| 3 | Ti_{0.67}Nb_{0.33}/0.1 μm | 7-8 | 0.01 | 1-2 |
| | (Ti_{0.67}Nb_{0.33})₁₋ₓNₓ where | | | |
| | x = 0.40-0.55/0.4 μm | | | |
| | Ir_{0.99}—C_{0.01}/10 nm | | | |
| 4 | Zr/0.5 μm | 11 | 0.001 | 11-12 |
| | ZrN/1 μm | | | |
| | Ir_{0.99}—C_{0.01}/10 nm | | | |
| 5 | Ta/0.05 μm | 10 | 0.001 | 17-18 |
| | TaC/0.5 μm | | | |
| | Ir_{0.991}—C_{0.009}/5 nm | | | |
| 6 | ZrB₂/0.3 μm | 7 | Pitting reaction after | |
| | Ir_{0.7}—B_{0.3}/5 nm | | 4 hours exposure | |

Only some illustrative layer systems are shown in Table 1. The layer systems advantageously display no increase in resistance at an anodic stress of +2000 mV relative to a standard hydrogen electrode in sulfuric acid solution at a temperature of 80° C. over a number of weeks. The layer systems applied in high vacuum by means of a sputtering or ARC process or in a fine vacuum by means of PECVD processes (plasma-enhanced chemical vapor deposition processes) had in some cases acquired a dark discoloration after this time of exposure. However, no visible corrosion phenomena or significant changes in surface resistances occurred.

### LIST OF REFERENCE NUMERALS

1a, 1b, 1c component
2 metal sheet
2′ coated metal sheet
2″ coated and formed metal sheet
2′″ remaining metal sheet
3 layer system
3a covering layer
4 undercoat layer system
4a first undercoat layer
4b second undercoat layer
5 gas distributor structure
10 bipolar plate
20 first roll of metal sheet
20′ second roll of remaining metal sheet
30, 30′ reel
100 plant
200a, 200b coating unit(s)
300 forming unit(s)
400 forming and/or shear cutting unit
500 stamping unit
600 transport unit

1. A process for producing components, in particular components for energy systems such as fuel cells or electrolyzers, the process comprising:
providing a first roll of metal sheet having a thickness of less than 500 μm;
rolling-off the metal sheet from the first roll by transporting a first end of the first roll in a direction of advance;
transporting the first end of the first roll and subsequent regions of the metal sheet through at least one coating plant in which the metal sheet is coated on at least one side by means of a physical and/or chemical vapor deposition process;
performing at least one forming process on the coated metal sheet;
forming a plurality of components by parting from the coated metal sheet; and
rolling-up the remaining coated metal sheet to give a second roll, with continuous transport of the metal sheet from the first roll to the second roll being carried out.

2. The process as claimed in claim 1, wherein the at least one forming process comprises deep drawing or extrusion or hydroforming.

3. The process as claimed in claim 1, wherein a layer system comprising a covering layer facing away from the metal sheet is applied to the metal sheet by means of the at least one coating plant, with the covering layer being formed by a homogeneous or heterogeneous solid metallic solution which either contains a first chemical element from the group of the noble metals in the form of iridium in a concentration of at least 99% or
contains a first chemical element from the group of the noble metals in the form of iridium and a second chemical element from the group of the noble metals in the form of ruthenium, with the first chemical element and the second chemical element being present in a total concentration of at least 99%,
and additionally contains at least one nonmetallic chemical element from the group consisting of nitrogen, carbon, and fluorine.

4. The process as claimed in claim 3, wherein the layer system further comprises an undercoat layer system where the undercoat layer system comprises at least one undercoat layer comprising at least one chemical element from the group consisting of titanium, niobium, hafnium, zirconium, and tantalum.

5. The process as claimed in claim 4, wherein the at least one undercoat layer comprises:
a first undercoat layer in the form of a metallic alloy layer comprising the chemical elements titanium and niobium; and
a second undercoat layer comprising at least one chemical element from the group consisting of titanium, niobium, hafnium, zirconium, tantalum and additionally at least one nonmetallic element from the group consisting of nitrogen, carbon, boron, fluorine.

6. The process as claimed in claim 5, wherein the second undercoat layer is arranged between the first undercoat layer and the covering layer.

7. A bipolar plate comprising at least one component which has been produced as claimed in claim 1.

8. The bipolar plate as claimed in claim 7, wherein the at least one component comprises two components which are joined to one another by bonding.

9. A fuel cell, in particular polymer electrolyte fuel cell, comprising at least one bipolar plate as claimed in claim 7.

10. An electrolyzer comprising at least one bipolar plate as claimed in claim 7.

11. A process for producing energy systems, the process comprising:
continuously transporting a metal sheet having a thickness of less than 500 μm from a first roller to a second roller;
coating the metal sheet with an undercoat layer system comprising at least one undercoat layer comprising at least one chemical element from the group consisting of titanium, niobium, hafnium, zirconium, and tantalum;
coating the metal sheet with covering layer formed by a homogeneous or heterogeneous solid metallic solution;
performing at least one forming process on the coated metal sheet; and
forming a plurality of components by parting from the coated metal sheet.

12. The process as claimed in claim 11, wherein the homogeneous or heterogeneous solid metallic solution contains:
a first chemical element from the group of the noble metals in the form of iridium in a concentration of at least 99%; and
at least one nonmetallic chemical element from the group consisting of nitrogen, carbon, and fluorine.

13. The process as claimed in claim 11, wherein the homogeneous or heterogeneous solid metallic solution contains:
a first chemical element from the group of the noble metals in the form of iridium and a second chemical element from the group of the noble metals in the form of ruthenium, with the first chemical element and the second chemical element being present in a total concentration of at least 99%; and
at least one nonmetallic chemical element from the group consisting of nitrogen, carbon, and fluorine.

14. The process as claimed in claim 11, wherein the at least one undercoat layer comprises:
a first undercoat layer in the form of a metallic alloy layer comprising the chemical elements titanium and niobium and
a second undercoat layer comprising at least one chemical element from the group consisting of titanium, niobium, hafnium, zirconium, tantalum and additionally at least one nonmetallic element from the group consisting of nitrogen, carbon, boron, fluorine.

15. The process as claimed in claim 14, wherein the second undercoat layer is arranged between the first undercoat layer and the covering layer.

16. The process as claimed in claim 11, further comprising bonding two components of the plurality of components to one another to form a bipolar plate.

17. A bipolar plate comprising two components bonded to one another, each component comprising:
a sheet metal substrate having a thickness of less than 500 μm;
an undercoat layer system comprising at least one undercoat layer comprising at least one chemical element from the group consisting of titanium, niobium, hafnium, zirconium, and tantalum; and
a covering layer formed by a homogeneous or heterogeneous solid metallic solution.

18. The bipolar plate as claimed in claim 17, wherein the homogeneous or heterogeneous solid metallic solution contains:
a first chemical element from the group of the noble metals in the form of iridium in a concentration of at least 99%; and
at least one nonmetallic chemical element from the group consisting of nitrogen, carbon, and fluorine.

19. The bipolar plate as claimed in claim 17, wherein the homogeneous or heterogeneous solid metallic solution contains:
a first chemical element from the group of the noble metals in the form of iridium and a second chemical element from the group of the noble metals in the form of ruthenium, with the first chemical element and the second chemical element being present in a total concentration of at least 99%; and
at least one nonmetallic chemical element from the group consisting of nitrogen, carbon, and fluorine.

20. The bipolar plate as claimed in claim 17, wherein the at least one undercoat layer comprises:
a first undercoat layer in the form of a metallic alloy layer comprising the chemical elements titanium and niobium and
a second undercoat layer, arranged between the first undercoat layer and the covering layer, comprising at least one chemical element from the group consisting of titanium, niobium, hafnium, zirconium, tantalum and additionally at least one nonmetallic element from the group consisting of nitrogen, carbon, boron, fluorine.
